(19) United States
(12) Patent Application Publication
(10) Pub. No.: US 2003/0129843 A1
(43) Pub. Date: Jul. 10, 2003

(54) Planarizing recess etch

(76) Inventors: Yongming Cai, Ann Arbor, MI (US); Linda P.B. Katehi, Zionsville, IN (US)

Correspondence Address: YOUNG & BASILE, P.C., Suite 624, 3001 West Big Beaver Road, Troy, MI, 48084-3107, US

(21) Appl. No.: 10/264,704

(22) Filed: Oct. 4, 2002

Related U.S. Application Data
(60) Provisional application No. 60/327,524, filed on Oct. 5, 2001.

(51) Int. Cl. H01L 21/311

(52) U.S. Cl. 438/694

(57) ABSTRACT

A method of planarizing a circuit surface is disclosed. The basic idea is to use the photoresist mask for etching as the mask for lift-off, i.e. after the substrate patterned with photoresist and dry etched, metal is directly deposited onto it and liftoff afterwards. Thus, the deposited metal is self aligned and filled into the etched pattern with a planar surface. It is important that the metal thickness should be the same as the etching depth. The lithography needs a special recipe and photoresist requires a special pre-treatment so that the metal can form a clean edge without any residual metal along the edge. A prototype using this invention, a MEMS switch, is introduced.

### CROSS-REFERENCE TO RELATED APPLICATION

This application claims the benefit of provisional application No. 60/327,524 which was filed on Oct. 5, 2001.

### STATEMENT REGARDING FEDERALLY SPONSORED RESEARCH OR DEVELOPMENT

The US Government has a paid-up license in this invention and the right in limited circumstances to require the patent owner to license others on reasonable terms as provided for by Grant No. RG 4336.

### FIELD OF THE INVENTION

The present invention relates to a process for planarizing a substrate, a product made by the process, and a product having a planarized substrate.

### BACKGROUND OF THE INVENTION

Micro-electro-mechanic-systems (MEMS) switches have been developed for broadband, low loss and high isolation microwave and millimeter wave circuits. For the MEMS switches fabrication, multiple layers of metal need to be deposited and lift-off to form three-dimensional structures. Usually, there are some metal residuals (with a height of 1 micrometer and a width of a fraction of micrometer) left on the edge of the circuit after lift-off. The edge is usually very sharp and following metal deposited on, the sharp edge it will break and discontinue the circuit. Also in micro-fabrication, as the number of levels in an interconnect technology increases, which results in poor step coverage of metal lines over the step, metal residual at the side of a step after anisotropic etching will reduce resolution (since the depth-of-field of sub-micron optical-lithography requires a surface to be planar within 0.5 μm). Currently, there are three methods to solve this problem: planarizing etch-back (PEB), electron cyclotron resonance CVD (ECRCVD) and chemical mechanical polishing (CMP). For PEB, sacrificial material is needed, which greatly increases the process complicacy. For ECRCVD, it requires a specialized CVD apparatus capable of doing low temperature CVD and RF-sputtering simultaneously. For CMP, it will introduce contamination from the etch slurry, deep scratches and residual embedded particles.

### SUMMARY OF THE INVENTION

The present invention provides a complete planar surface for multilevel interconnect system in microelectronic and MEMS fabrication with roughness less than 500 Å, with one step photolithography. The present invention can be achieved without any special tools and enhances the efficiency greatly. First photoresist is applied onto the substrate, then baked on a hot plate for a certain period of time at a specific temperature. Then the substrate is soaked in chlorobenzene for a specific time and then taken out to do the photolithography. After that, the substrate is dry etched with a conventional reactive ion etching (RIE) machine. Metal is then deposited onto the dry etched substrate and lift-off after metal deposition. Since the grooves have been etched during RIE and photoresist is still on the substrate during the deposition, the deposited metal is self aligned and filled into the grooves. The timing of baking and soaking is an important part of this technique. The substrate etching can also use wet etch. Due to its simplicity, various kinds of substrate (such as GaAs, InP, Si, quartz, etc.) can be used and filled with different materials (any metal and low temperature deposited dielectric). Since this approach is inherently planar and self-aligned, it allows fabrication of three or more levels of metals and solves the fundamental problem previously encountered in micro-fabrication. The method has been performed to produce several working prototypes.

Other applications of the present invention will become apparent to those skilled in the art when the following description of the best mode contemplated for practicing the invention is read in conjunction with the accompanying drawings.

### BRIEF DESCRIPTION OF THE DRAWINGS

The description herein makes reference to the accompanying drawings wherein like reference numerals refer to like parts throughout the several views, and wherein:

FIG. 1 is a surface profile for a gold (Au) contact;

FIG. 2 illustrates the formation of the metal residual at the edge;

FIG. 3 depicts a Dektek profile after RIE etch of the silicon bare wafer and before deposition;

FIG. 4 illustrates after deposition of aluminum (Al) and lift-off of aluminum (Al), the grooves were filled with approximately 1.1 μm of aluminum with raised ridges of δ<200 Å at opposite edges;

FIG. 5 shows an expected profile after lift-off with precise etching and metal deposition;

FIG. 6 depicts a crevice on the photoresist after the chlorobenzene treatment;

FIG. 7 shows the morphology after lift-off the SEM of the circuit;

FIG. 8A is a series switch with bridge structure according to the present invention;

FIG. 8B is an enlarged beam section;

FIG. 8C is an enlarged RF contact;

FIGS. 9A through 9G progressively illustrates various steps of the process according to the present invention;

FIG. 10 is a simulated return loss and isolation when the switch is in the off condition or up state;

FIG. 11 is a simulated return loss and insertion loss when the switch is in the on condition or down state;

FIG. 12 is a measured return loss and isolation loss when the switch is in the off condition or up state; and

FIG. 13 is a measured return loss and insertion loss when the switch is in the on condition or down state.

### DESCRIPTION OF THE PREFERRED EMBODIMENT

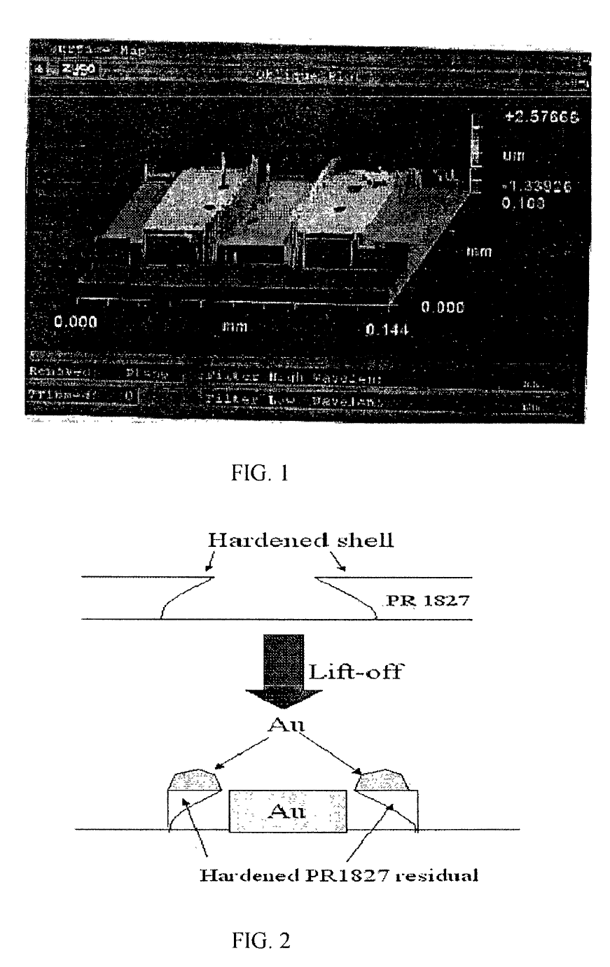

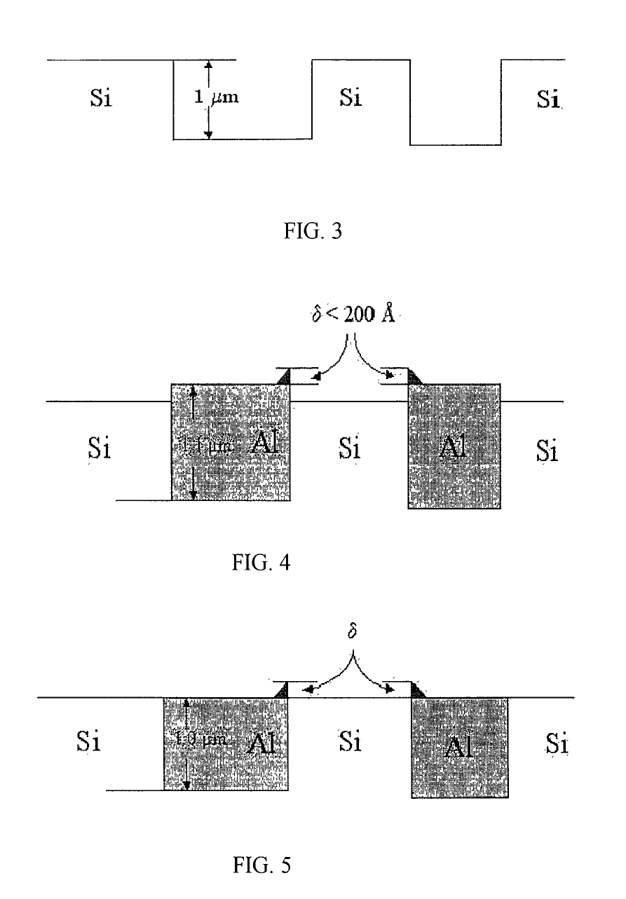

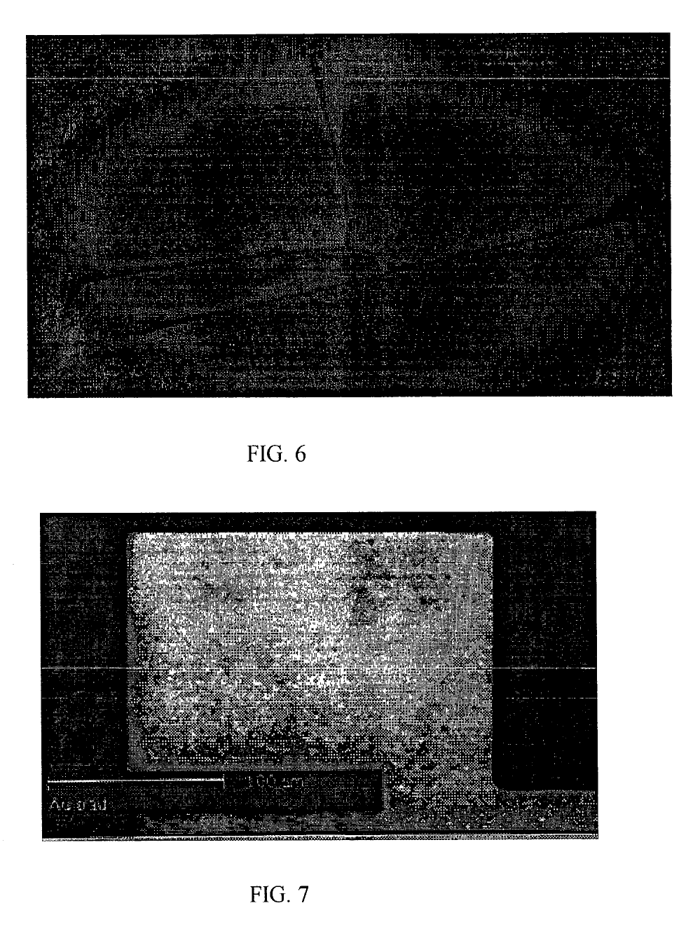

Surface planarization has been a long-time problem in switch fabrication. As shown in the attached surface profile of FIG. 1 for a gold (Au) contact shown as the upper rectangular surface broken at the middle by two edges. The two edges were left-over from the last steps of the fabrication process. In the last steps, chlorobenzene was used in lithography to generate undercuts in the photoresist PR1827. Since the chlorobenzene was pre-baked at 105° C., it formed a hard shell at the furnace and is difficult to remove during processing. So when metal was deposited and the PR1827 lifted-off, the hardened PR1827 was left and the gold (Au) deposited on the photoresist residual was left too. This resulted in the formation of two undesirable sharp edges. This is illustrated in FIG. 2. To correct this undesirable result, the processing is modified to reduce the PR1827 residual and improve lift-off of the PR1827. The temperature of the pre-bake is decreased and the soaking time in chlorobenzene is manipulated. The morphology of the PR1827 after baking and treating in chlorobenzene was improved. The following process steps were found to provide acceptable morphology of the PR1827: (1) spin at 3.5 km for 30 seconds; (2) soft-bake at 80° C. for 100 seconds; (3) soak in chlorobenzene for 4 minutes; (4) blow dry with small N₂ flux; (5) photolithography immediately; and (6) develop in MF351 for 35 seconds. The processing procedure was conducted as follows: (1) a silicon (Si) bare wafer was cleaned by the Pirahra method and etched with silicon oxide (SiO₂); (2) lithography as previously described was performed on the silicon bare wafer with an appropriate circuit mask; (3) the wafer was placed in an RIE etch chamber to etch the silicon bare wafer for 20 minutes, where the SF₀ flow=12 sccm, O₂ flow=3 sccm, pressure=10 mTorr, power=50 W, and etch rate=500 angstrom(Å)/minute, and after a 1 μm groove was etched on the surface of the silicon bare wafer, the wafer was removed from the RIE etch chamber; (4) the wafer was immediately placed into a metal deposition chamber and 1 μm of aluminum (Al) was evaporated and deposited at a rate of 15 Å/second; (5) lift-off in PRS-2000 for 10 hours; and (6) the surface was cleaned and measured. The Dektek profile after RIE etch of the silicon bare wafer and before deposition is shown in FIG. 3. It was a silicon surface with 1 μm groove etched into the surface. After deposition of aluminum (Al) and lift-off of aluminum (Al), the grooves were filled with approximately 1.1 μm of aluminum with raised ridges of δ<200 Å at opposite edges, as shown in FIG. 4. It appeared that the aluminum was over-deposited by 1000 Å, and this could have been the result for two possible reasons: (1) aluminum is a low-mass material and the crystal thickness measurement does not indicate the correct thickness; and/or (2) the RIE etch does not give the precise etch depth and between about 200 Å to 300 Å error is a typical phenomenon. The outer edges of the grooves are raised by 6 with an additional height of less the 200 Å, which is a good result for surface planarization. The next step was to precisely control the RIE time and also to control the evaporation time to gain a completely flat surface. The expected profile should look similar to FIG. 5. The lithography process was changed slightly to remove crevices (as shown in FIG. 6) that appeared in the photoresist surface after the RIE in the previous process. The photoresist looked intact after RIE this time. The wafer was also placed in hot PRS-2000 for 10 hours instead of cold PRS-2000 to achieve better lift-off results. The SEM (FIG. 7) shows the morphology of the circuit after all the modification to the process. Clearly, there is no obvious metal residual at the edge. From the measurement with the Dektek, there appeared some undulations on the wafer surface (less the 200 Å). This phenomenon can possibly result for two reasons. First, the RIE gives uniformity as 4.4% (as shown on the data sheet generated by the SSEL staff) for etching silicon, so when etching 10,000 Å silicon this will result in etch depth variation around 440 Å. Different locations were measured on the wafer and a mean value of 100732 Å was chosen after etching, although the expected value is 10,000 Å. It is believed that additional experiments can be conducted to modify the etching time and to rotate the wafer during etching to achieve better uniformity. Second, the metal deposition has some internal error when depositing the metal. Since the metal source was still hot after the e-beam power is shut down, some metal atoms are flying out of the source and depositing onto the wafer even after the deposition step was finished. From the crystal thickness monitor, it can be observed that this characteristic gives an extra 40 Å metal. The crystal could also have an error associated with it. The procedure described above resulted in some photoresist residuals along the edge of the pattern with a height of around 200 Å to 400 Å that may have resulted from the hot PRS-2000.

### EXAMPLES

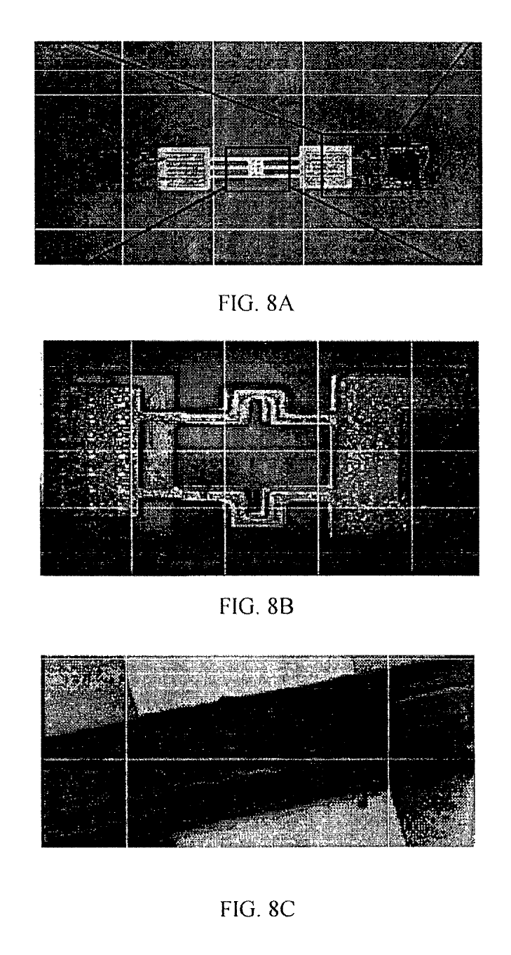

A new type of MEMS switch is provided according to the present invention. This switch has been fabricated with parylene serving as a structure material and polyamide as a sacrificial layer as best seen in FIG. 8. The whole process can be implemented at low temperature (the highest thermal cycle is approximately 30 min of approximately 150° C. baking) with transistor such as CMOS or HBT.

The finished switch is shown in FIG. 8A. The bridge has a length around 950 μm and is suspended 2.5 μm above the substrate. The deflection from that level is of the order of a fraction of a micron. A meander connection beam shown in the FIG. 8B is introduced as two supporting beams to enhance the ability of stretching and to reduce stress generated in the beam during releasing. Two actuation pads (200 μm×200 μm) are fabricated on the bridge. Another pair of actuation pads are on the circuit. When direct current (DC) bias is applied between the pads on the bridge and on the circuit, the switch is pulled down. As shown in FIG. 8C, the switch is very flat when fully released due to low build in stress. The metal is underneath the parylene beam at the RF contact.

Parylene is a commercially available polymer used as a protective Planar Circuit Board (PCB) coating. Its special properties make it an ideal material for MEMS switch. The parylene can be deposited at room temperature. Parylene can form very thin layers. For parylene as thin as 0.1 μm, the DC breakdown voltage is as high as 800 V. For 3 μm thick, it can sustain 2000 V. Parylene can resist room temperature chemical attack and is insoluble in all organic solvent up to 150° C. Parylene has a low Young=s modulus (around 2.5 GPa), large elongation to break (200%) and low density 1.29 g/cm3. Parylene is truly conformal and pinhole free at thickness down to 0.4 μm. Due to the above reasons, parylene was chosen as the switch material. The final structure has low stress and is flat and self-supportive.

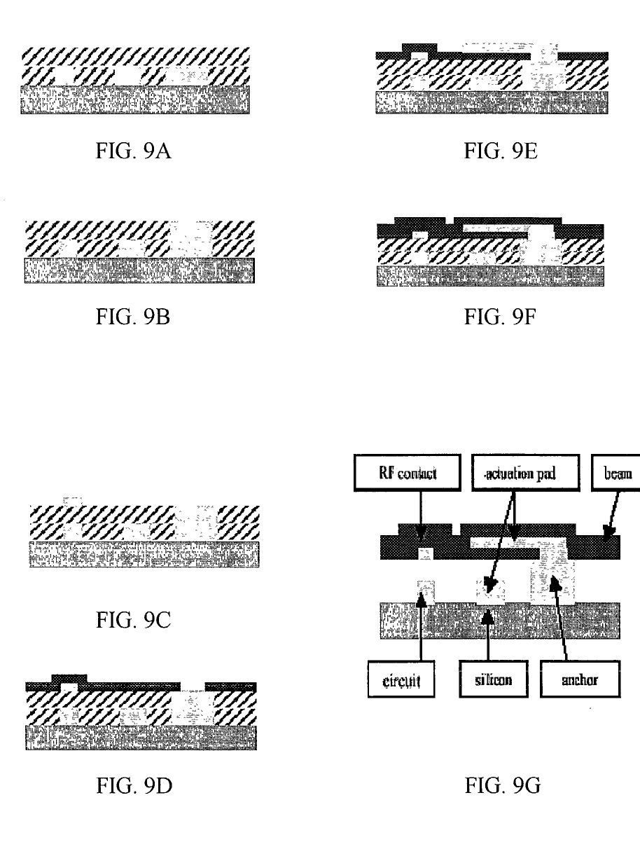

The switch has been designed to be a metal-to-metal contact series switch. The switch is illustrated in a bridge form as shown in FIG. 8. The pull-in voltage varies to be between 10-20V inclusive, depending on the thickness and length of the beam. Coplanar Waveguide (CPW) line is used as the transmission line. The CPW line has dimensions of (S/W/S=40/60/40 μm) chosen for 50 Ω at 30 Ghz. The processing procedure as shown in FIGS. 9A-9G consists of the following steps:

1) Deposit Au as circuit layer and planarize the surface. During the RF circuit metalization, usually 8000-9000 Å Au layer will cause a hilly profile for the sacrificial layer and will warp the structure deposited on it. The present invention uses the planarizing process described herein to planarize the surface.

2) Apply polyamide onto the chip as a sacrificial layer. Bake at 150° C. for 30 min. This is the only thermal process in this fabrication. After baking, the polyamide is 2.5 μm thick.

3) RIE etch the sacrificial layer and deposit Au to form the anchor.

4) Deposit Au and lift-off to make the RF contact which is 8000 Å thick.

5) Deposit 0.5 μm parylene.

6) Deposit and lift-off to make the inner beam for electro-actuation.

7) Deposit 2.5 μm parylene and RIE to define the bridge.

8) Remove the sacrificial layer.

9) Release the structure with critical point drying. The diagram of FIG. 9G shows one half of the bridge.

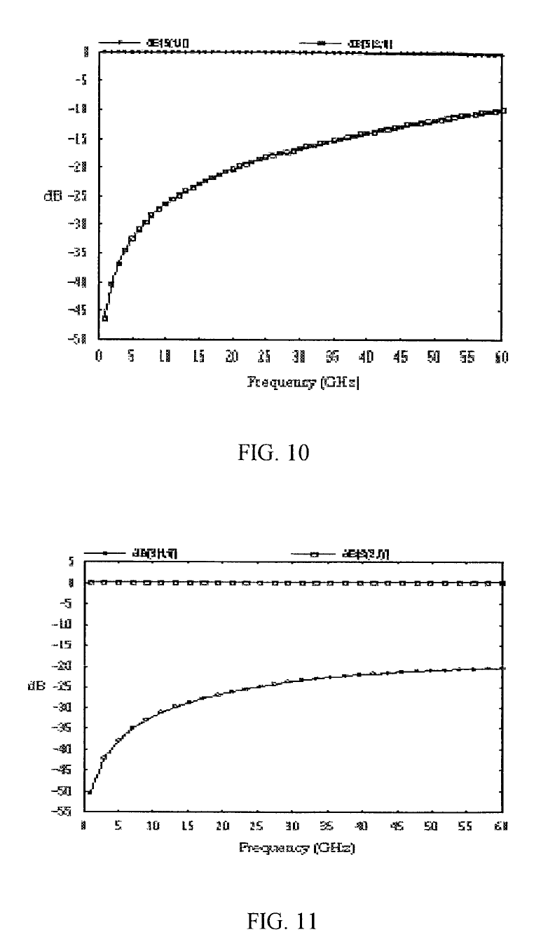

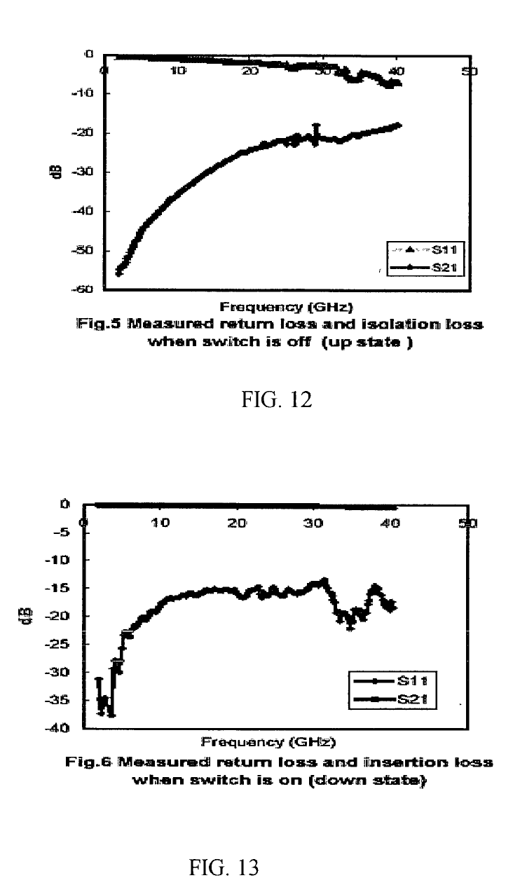

The Zeland IE3D simulated results are shown in FIG. 10. and FIG. 11. The switch has a calculated isolation of 50 dB (at DC) to 15 dB (at 40 GHz) when the switch is in the off condition, and 0 dB insertion loss when the switch is in the on condition since the simulation includes zero losses.

The measurements are based on an on-wafer Thru-Reflection-Line (TRL) calibration. The isolation ranges from 50 dB at 2 GHz to 15 dB at 40 GHz, when the switch is in the off state, as shown in FIG. 12. When the switch is in the on state, the insertion loss has been measured as illustrated in FIG. 13 to be 0.5 dB at from DC to 40 GHz. There are some discrepancies between the simulation and the measured results because of this measured loss. The loss is partially due to the SiO₂ left on the silicon wafer to avoid possible Schottky barriers between the circuit layer and the Si substrate. It has been found that the loss associated with silicon oxide is higher than that of Si. In the future, the dielectric material on the substrate between the signal line and the finite ground line of the CPW line will be removed. The bottom of the RF contact is coated with chromium and it incurs loss higher than Au. Also when two metals (Au and Cr) contact each other, the difference in work function causes higher loss than contact between just Au. In the future, the chromium will be removed too.

The disclosure of provisional patent application No. 60/327,524 filed on Oct. 5, 2001 is incorporated by reference herein.

While the invention has been described in connection with what is presently considered to be the most practical and preferred embodiment, it is to be understood that the invention is not to be limited to the disclosed embodiments but, on the contrary, is intended to cover various modifications and equivalent arrangements included within the spirit and scope of the appended claims, which scope is to be accorded the broadest interpretation so as to encompass all such modifications and equivalent structures as is permitted under the law.

What is claimed is:

1. A process for manufacturing a planarized substrate comprising the steps of:
baking a substrate with applied photoresist for a predetermined period of time at a predetermined temperature; and
soaking the baked substrate in chlorabenzene for a predetermined time.

2. The process of claim 1 further comprising the steps of:
performing photolithography on the substrate after soaking in the chlorabenzene; and etching the wafer in an RIE machine.

3. The process of claim 1 further comprising the steps of:
depositing metal on the etched substrate right after the etching step; and
performing lift-off after the metal depositing step.

4. The process of claim 1 further comprising the steps of:
applying photoresist to the substrate prior to the baking step.

5. The process of claim 1 further comprising the steps of:
providing a layer of parylene forming a bridge structure material for a switch and polyamide acting as a sacrificial layer.

6. The process of claim 5 further comprising the steps of:
during the baking step, subjecting the substrate with applied photoresist to a thermal cycle of at most approximately 150° C. for at most approximately 30 minutes.

7. The process of claim 1 further comprising the steps of:
forming a bridge with a length of approximately 950 μm and suspended approximately 2.4 μm above the substrate.

8. The process of claim 1 further comprising the steps of:
depositing metal as a circuit layer prior to the baking step;
applying polyamide as a sacrificial layer; and
performing the baking step at 150° C. for 30 minutes.

9. The process of claim 8 for manufacturing a MEMS switch further comprising the steps of:
etching the sacrificial layer and deposited metal to form an anchor;
depositing metal and performing lift-off to form the RF contact approximately 8000 Å thick;
depositing approximately 0.5 μm layer of parylene;
depositing and performing lift-off to form an inner beam for electroactuation;
deposit approximately 2.5 μm layer of parylene;
etching the layer of parylene to define the bridge;
removing the sacrificial layer; and
releasing the bridge with critical point drying.

10. A planarized substrate manufactured according to the method of claim 1 comprising:
a substrate with applied photoresist baked for a predetermined period of time at a predetermined temperature; and
the baked substrate soaked in chlorabenzene for a predetermined time.

11. The planarized substrate of claim 10 further comprising:
photolithography performed on the substrate after being soaked in chlorabenzene; and
the substrate etched in an RIE machine.

12. The planarized substrate of claim 10 further comprising:
metal deposited on the etched substrate immediately after etching; and
lift-off performed after the metal is deposited.

13. The planarized substrate of claim 10 further comprising:
photoresist applied to the substrate prior to baking.

14. The planarized substrate of claim 10 further comprising:
a layer of parylene forming a bridge structure material for a switch and polyamide acting as a sacrificial layer.

15. The planarized substrate of claim 14 further comprising:
the substrate with applied photoresist subjected to a thermal cycle of at most approximately 150° C. for at most approximately 30 minutes during baking.

16. The planarized substrate of claim 10 further comprising:
a bridge formed with a length of approximately 950 μm and suspended approximately 2.4 μm above the substrate.

17. The planarized substrate of claim 10 further comprising:
metal deposited as a circuit layer prior to baking;
polyamide applied as a sacrificial layer; and
the layers baked at 150° C. for 30 minutes.

18. The planarized substrate of claim 17 for manufacturing a MEMS switch further comprising:
the sacrificial layer and deposited metal etched to form an anchor;
metal deposited and lift-off performed to form an RF contact approximately 8000 Å thick;
a layer of parylene approximately 0.5 μm thick deposited;
an inner beam for electro-actuation formed by deposit and lift-off of material;
a layer of parylene approximately 2.5 μm thick deposited;
the layer of parylene etched to define the bridge;
the sacrificial layer removed; and
the bridge released with critical point drying.

19. A planarized substrate comprising:
a substrate with applied photoresist baked for a predetermined period of time at a predetermined temperature; and
the baked substrate soaked in chlorabenzene for a predetermined time.

20. The planarized substrate of claim 19 further comprising:
photolithography performed on the substrate after being soaked in chlorabenzene; and
the substrate etched in an RIE machine.

21. The planarized substrate of claim 19 further comprising:
metal deposited on the etched substrate immediately after the etching step; and
lift-off performed after the metal is deposited.

22. The planarized substrate of claim 19 further comprising:
photoresist applied to the substrate prior to baking.

23. The planarized substrate of claim 19 further comprising:
a layer of parylene forming a bridge structure material for a switch and polyamide acting as a sacrificial layer.

24. The planarized substrate of claim 23 further comprising:
the substrate with applied photoresist subjected to a thermal cycle of at most approximately 150° C. for at most approximately 30 minutes during baking.

25. The planarized substrate of claim 19 further comprising:
a bridge formed with a length of approximately 950 μm and suspended approximately 2.4 μm above the substrate.

26. The planarized substrate of claim 19 further comprising:
metal deposited as a circuit layer prior to baking;
polyamide applied as a sacrificial layer; and
the layers baked at 150° C. for 30 minutes.

27. The planarized substrate of claim 26 for manufacturing a MEMS switch further comprising:
the sacrificial layer and deposited metal etched to form an anchor;
metal deposited and lift-off performed to form an RF contact approximately 8000 Å thick;
a layer of parylene approximately 0.5 μm thick deposited;
an inner beam for electro-actuation formed by deposit and lift-off of material;
a layer of parylene approximately 2.5 μm thick deposited;
the layer of parylene etched to define the bridge;
the sacrificial layer removed; and
the bridge released with critical point drying.
